(19) United States
(12) Patent Application Publication
(10) Pub. No.: US 2026/0323854 A1
(43) Pub. Date: Oct. 15, 2026

(54) ELECTRICAL DEVICE

(71) Applicant: SEW-EURODRIVE GMBH & CO. KG, Bruchsal (DE)

(72) Inventors: Rolf JANZER, Bruchsal (DE); Horst FRANK, Öbstringen-Odenheim (DE)

(73) Assignee: SEW-EURODRIVE GMBH & CO. KG, Bruchsal (DE)

(21) Appl. No.: 19/484,966

(22) PCT Filed: Apr. 23, 2024
(86) PCT No.: PCT/EP2024/061130

§ 371 Date: Nov. 17, 2025

(30) Foreign Application Priority Data
May 16, 2023 (DE) 10 2023 002 007.9

(51) Int. Cl. H05K 5/04; H05K 5/02; H05K 7/20

(52) U.S. Cl. CPC H05K 5/04; H05K 5/0217; H05K 7/20136

(57) ABSTRACT

An electrical device includes a power electronics and a line filter. The line filter has a housing, the power electronics has a sheet-metal housing, and an electrical PE connection or ground connection is formed between the sheet-metal housing and the housing by an angle bracket that includes a first limb region, a second limb region, and a yoke region, as well as a lug region. The yoke region is connected to both the first limb region and the second limb region, at least two first press-in nuts are arranged in the second limb region and at least two second press-in nuts are arranged in the lug region, and the angle bracket is pushed onto a sheet-metal region of the sheet-metal housing such that the sheet-metal region is arranged between the first and the second limb region and makes contact with the first limb region and the second limb region. First screws are screwed into the first press-in nuts and project through the first limb region, the sheet-metal region and the second limb region so that the sheet-metal region is clamped between the first and the second limb region, and second screws are screwed into the second press-in nuts and project through the housing.

### FIELD OF THE INVENTION

The present invention relates to an electrical device.

### BACKGROUND INFORMATION

In certain conventional systems, an electrical appliance has a heat-generating component, such as a power semiconductor, which is in contact with a heat sink for heat dissipation.

An electrical control device is described in German Patent Document No. 10 2017 206 775.

### SUMMARY

Example embodiments of the present invention provide an electrical device, in which ready production and/or maintenance is possible.

According to example embodiments, an electrical device, e.g., a converter or inverter, includes power electronics and a line filter. The line filter has a housing, e.g., made of sheet metal, the power electronics has a sheet-metal housing, an electrical PE connection or ground connection is formed between the sheet-metal housing and the housing by an angle bracket, and the angle bracket has a first limb region, a second limb region and a yoke region as well as a lug region. For example, the first limb region is spaced apart from the second limb region. The yoke region is connected to both the first limb region and the second limb region. For example, the lug region is adjacent to the first limb region, and the yoke region with the first and second limb regions form a U-shaped region of the angle bracket. At least two first press-in nuts are arranged in the second limb region, at least two second press-in nuts are arranged in the lug region, and the angle bracket is pushed onto a sheet-metal region of the sheet-metal housing such that the sheet-metal region is arranged between the first and the second limb region and makes contact with the first limb region and the second limb region. First screws are screwed into the first press-in nuts and project through the first limb region, the sheet-metal region and the second limb region so that the sheet-metal region is clamped between the first and the second limb region. For example, the respective screw head of the respective first screw presses the first limb region onto the sheet-metal region and the latter is pressed onto the second limb region. Second screws are screwed into the second press-in nuts and project through the housing, e.g., so that the respective screw head of the respective second screw presses the housing onto the lug region.

An advantage of this is that the line filter can be connected to the power electronics and a secure ground connection or PE connection is still provided by the angle bracket. The connection is nevertheless secure, as at least two press-in nuts and screws are provided on the housing and sheet-metal housing sides. Connecting is quick and ready by fitting on the angle bracket and screwing on the first screws. After this, the housing must be placed against the lug region and the second screws tightened.

This makes production particularly ready and yet safe.

According to example embodiments, the angle bracket is arranged as a punched and bent part made of sheet metal. An advantage of this is that ready, cost-effective production is possible.

According to example embodiments, a protective cover, e.g., made of plastic, is arranged on the housing in a displaceable manner. In a first displacement position of the protective cover, the angle bracket is accessible from the surroundings of the electrical device, e.g., so that the second screws can be actuated with a tool, and, in a second displacement position the protective cover surrounds the angle bracket in a housing-forming manner, i.e., for example, the angle bracket is not accessible from the surroundings. An advantage of this is that the angle bracket can be protected against contact.

For example, the protective cover is clip-connected to the housing of the line filter in the second displacement position.

According to example embodiments, a plug connector part is arranged on the line filter, which is plug-connected to a corresponding mating plug connector part of the power electronics. An advantage of this is that additionally an electrical connection is produced when the housing is connected to the sheet-metal housing.

According to example embodiments, the lug region on the first limb region is bent at a right angle. An advantage of this is that the lug region projects, thus making it possible to connect the line filter to the power electronics.

According to example embodiments, the line filter has a choke via which the current supplying the power electronics is conducted. An advantage of this is that the choke is arranged in the interior region of the line filter and is thus able to dissipate heat in a cooling air flow.

According to example embodiments, the air flow exiting the sheet-metal housing flows through the housing of the line filter, e.g., past the choke. An advantage of this is that the choke is cooled by the air flow.

According to example embodiments, the electrical device, e.g., a converter or inverter, includes a sheet-metal housing and a fan, and the fan has a fan housing which is clip-connected to the sheet-metal housing and has a pivot pin which is set against a pivot axis oriented coaxially to an edge of the sheet-metal housing for pivoting the fan relative to the sheet-metal housing, e.g., which pivot pin is set against a pivot axis oriented coaxially to an edge of the sheet-metal housing for rotating the fan relative to the sheet-metal housing. For example, the pivoting of the fan housing is blocked by the clip connection and/or can be carried out after the clip connection has been released.

An advantage of this is that the fan can be connected to the sheet-metal housing or separated from the sheet-metal housing. The electrical device can thus also be operated without the fan. However, the fan can be clipped on as an option to provide more powerful cooling. The connection method includes or substantially consists of two steps: first, placing the fan housing against the edge of the sheet-metal, and then pivoting it about the axis of rotation until clipping into place occurs. When making this connection, an electrical plug connection can also be connected so that the electric motor of the fan can be supplied with power.

According to example embodiments, a latching lug is formed on the fan housing, which latching lug is clipped into a recess or cut-out in the sheet-metal housing. An advantage of this is that the latching lug is formed in one piece on the fan housing, thus providing a secure and resilient clip connection.

According to example embodiments, guide pins are formed on the fan housing, which guide the fan housing at least when releasing or closing the clip connection. An advantage of this is that jamming during clipping can be prevented, thus making the connection reliable and without malfunction.

According to example embodiments, the fan housing, including the pivot pin, guide pin, and/or latching lug, is made of injection-molded plastic, e.g., in one piece and/or one part. An advantage of this is that ready, cost-effective production is possible.

According to example embodiments, the fan housing has a receiving region for a fan wheel driven by an electric motor and a region which is narrowed such that the air flow conveyed by the fan wheel is narrowed as it flows through the narrowed region, thus increasing its average flow velocity. An advantage of this is that the air flow enters the interior region enclosed by the sheet-metal housing at an increased speed, thus achieving a high cooling capacity.

According to example embodiments, the narrowed section is rounded such that the airflow passing through the narrowed section is deflected by 90° from the fan in a direction perpendicular to the rotational axis of the fan wheel and flows through front grille openings of the sheet-metal housing, e.g., through those facing the fan, into the interior of the electrical appliance, e.g., into the interior region enclosed by the sheet-metal housing. An advantage of this is that only a flat structure is required on the sheet-metal housing.

According to example embodiments, the sheet-metal housing has further grille openings arranged on the side of the electrical device, through which openings the air flow flowing through the electrical device draws in an additional air flow, e.g., which thus increases the volume flow and also cools laterally arranged heat loss sources of the electrical device and cools the sheet-metal housing. For example, third grille openings are arranged on the side of the electrical device opposite the fan, through which third grille openings the entire air flow exits. An advantage of this is that the air flow conveyed by the fan wheel flows through the interior region enclosed by the sheet-metal housing and draws in a lateral inflow, so that a high cooling capacity can be achieved. For this purpose, the sheet-metal housing, which, for example, is substantially cuboid in shape, has grille openings on at least three of its six sides, so that air flows in through two of the sides and flows out through the third side. The second side is adjacent to the first side. For example, the third side is arranged opposite the first side.

According to example embodiments, the fan hood is arranged such that the flow cross-section in the narrowed region decreases monotonically with increasing distance from the fan wheel. For example, initially a width of the interior region of the fan made available to the air flow by the fan hood becomes monotonically smaller and then a height of the interior region of the fan made available to the air flow by the fan hood becomes increasingly smaller. For example, the width is measured in a direction parallel to the nearest surface of the sheet-metal housing and the height is measured in a direction parallel to the normal direction of the nearest, e.g., flat, surface. An advantage of this is that the air flow is initially narrowed in a first direction and then in a second direction perpendicular to the first direction.

The narrowing thus does not occur isotropically transverse to the flow direction, but rather anisotropically transverse to the flow direction in a time-shifted manner.

According to example embodiments, the electrical device, e.g., a converter or inverter, has power electronics, e. g., a power part, and signal electronics, e. g., a control part. The power electronics has a sheet-metal housing having a cover to form a housing, the signal electronics has a signal electronics housing which is placed on the power electronics, the cover has a connecting lug, through which a mating plug connector part of the power electronics projects, a plug connector part of the signal electronics is connected to the mating plug connector part, a guide groove is formed in the cover, e. g., the guide groove extends parallel to the plug connection direction, and a guide rib formed on an inner side of the signal electronics housing projects into the guide groove and/or is guided thereby. At least one first centering dome is arranged on the sheet-metal housing and projects towards the signal electronics housing, and a screw projects through the centering dome, which also projects through the signal electronics housing and is screwed into a threaded bore of the power electronics. A hollow centering dome, e. g., formed from plastic, is formed on the connecting lug and projects towards the signal electronics housing, e. g., parallel to the plug connection direction of the plug connection formed from the plug connector part and the mating plug connector part. A pin, e.g., a cross pin, is formed on the signal electronics housing, which pin projects into the hollow centering dome, e.g., for centering the signal electronics housing relative to the sheet-metal housing.

An advantage of this is that tilting is avoided when the signal electronics are placed on the power electronics, as the pin, the guide groove, and the plug connection itself represent three centering devices with different modes of action. Overdetermination, but with different modes of action and thus differently directed tolerances, prevents tilting. The cover is a centrally important centering device, as it provides the majority of the centering.

According to example embodiments, the connecting lug on the cover is formed at an angle. An advantage of this is that different spatial directions are taken into account when aligning the signal electronics housing.

According to example embodiments, the cover is an injection-molded plastic part. An advantage of this is that ready, cost-effective production is possible, and the centering devices can be readily integrated by shaping without additional effort.

According to example embodiments, pins formed on the cover and projecting therefrom extend into recesses or cut-outs in a base plate of the electrical device, the sheet-metal housing is connected to the base plate, and a sheet-metal edge of the sheet-metal housing projects into a groove of the cover. For example, the sheet-metal edge is pivoted into the groove by a pivoting movement about the connecting line of the pins, e.g., when the electrical device is mounted, e. g., and thus projects into the groove. An advantage of this is that the smallest clear diameter of the recesses is larger than the largest outer diameter of the pins. This allows the cover to be pivoted with the pins plugged into the recesses. During this pivoting movement, which is carried out after the pins have been plugged into the recesses, the sheet-metal edge is inserted into the groove, e.g., pivoted into it.

According to example embodiments, the cover has a knockout region, and, for example, a screw becomes accessible after the knockout region is knocked out, which screw secures an electrical ground connection or PE connection. An advantage of this is that this connection can be disconnected or closed without any other changes being made and that thus no testing, such as high-voltage testing or similar, is necessary.

According to example embodiments, the electrical device, e. g., the power electronics, includes a circuit board which is equipped with a heat-generating component, e. g., a power semiconductor, a heat sink having at least one cooling fin, and a housing part of the sheet-metal. A bushing, e.g., a press-fit bushing, is plugged into a cut-out in the cooling fin, a screw, the screw head of which presses the printed circuit board, together with the component, towards the heat sink, is screwed into an internal thread of the bushing, and the bushing has a polyhedral region which is pressed into the housing part.

An advantage of this is that, on the one hand, the bushing is firmly connected to the housing part, and, on the other hand, when screwed into the bushing, the screw positions and/or presses the bushing against a step of the heat sink. This presses the printed circuit board with the component against the heat sink and improves and ensures heat transfer. At the same time, the screw together with the press-in nut serves as an electrical ground connection for the housing part in order to connect it to a conductive path on the printed circuit board.

To increase the safety of the electrical ground connection, the connection can optionally be implemented as a double connection and thus more securely.

According to example embodiments, the bushing has a toothing which is cut into the material of the cooling fin. The heat sink is thus also electrically securely connected to the bushing and thus also to the screw and the housing part, and is grounded, and a PE connection can also be implemented instead of the ground connection.

According to example embodiments, the toothing is an external toothing. An advantage of this is that the toothing cuts into the cut-out of the heat sink.

According to example embodiments, the screw projects through the heat sink, e.g., through the cooling fin. An advantage of this is that there is an electrical connection between the printed circuit board and the housing part.

According to example embodiments, the housing part is arranged on the side of the heat sink facing away from the printed circuit board and/or the printed circuit board is arranged on the side of the heat sink facing away from the housing part. An advantage of this is that the housing part can be electrically connected by the screw to a conductive path of the printed circuit board, which can be arranged on the other side of the heat sink in a mechanically protected manner.

According to example embodiments, the housing part is made as a punched and bent part from a sheet metal. An advantage of this is that ready production is possible.

According to example embodiments, the polyhedral region is arranged flush with the housing part on at least one side of the housing part, e.g., on the side of the housing part facing away from the heat sink.

According to example embodiments, the polyhedral region projects radially from the bushing. An advantage of this is that a high level of rotational safety can be achieved.

According to example embodiments, the polyhedral region is spaced from the toothing. An advantage of this is that the housing part is spaced from a step of the receiving region of the printed circuit board against which the bushing is positioned.

According to example embodiments, the cut-out is an interruption in the cooling fin. An advantage of this is that the cooling fin has a thickened region in which a bore is provided as a cut-out.

According to example embodiments, the bushing is made of steel. An advantage of this is that ready, cost-effective production is possible.

According to example embodiments, the heat sink is made of aluminum. An advantage of this is that the bushing cuts readily into the material of the heat sink.

According to example embodiments, the cooling fin has a thickening which is interrupted by the cut-out, e.g., the bushing is plugged into the cut-out and is thus received in the thickening. An advantage of this is that receiving the bushing is ready and safe.

According to example embodiments, a further bushing, e. g., a further press-fit bushing, is plugged into a further cut-out of a further cooling fin of the heat sink, a further screw, the screw head of which presses the printed circuit board, together with a further component, towards the heat sink, is screwed into an internal thread of the further bushing, the further bushing has a further polyhedral region which is also pressed into the housing part, the further bushing has a further toothing which is cut into the material of the further cooling fin, the further toothing is also an external toothing, the further screw projects through the heat sink, e.g., through the further cooling fin. An advantage of this is that a sufficiently secure ground connection can be established. This is because the two screws act as an independently functioning electrical ground line or PE line. If one of the screws fails, the respective other screw ensures that the function is maintained.

Further features and aspects of example embodiments of the present invention are explained in more detail below with reference to the appended of schematic Figures.

### BRIEF DESCRIPTION OF THE DRAWINGS

FIG. 1 is a cross-sectional view through a region of an electrical device, in which a bushing 1 is used.

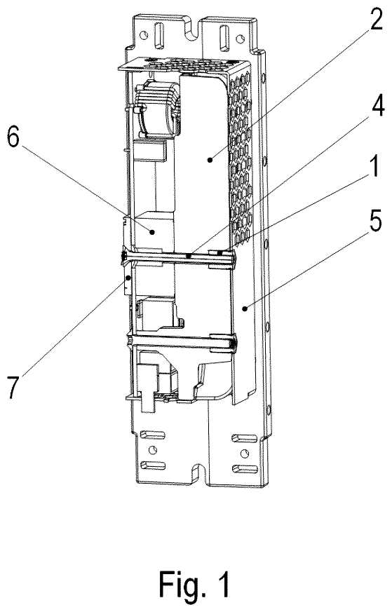

FIG. 2 is a perspective view of a portion of the electrical device.

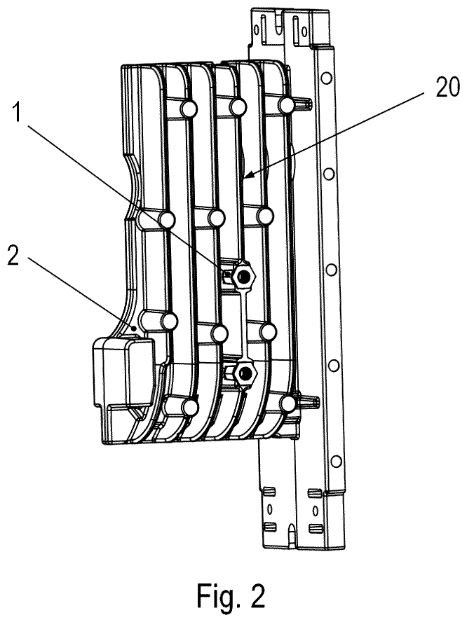

FIG. 3 is a perspective view of the bushing 1.

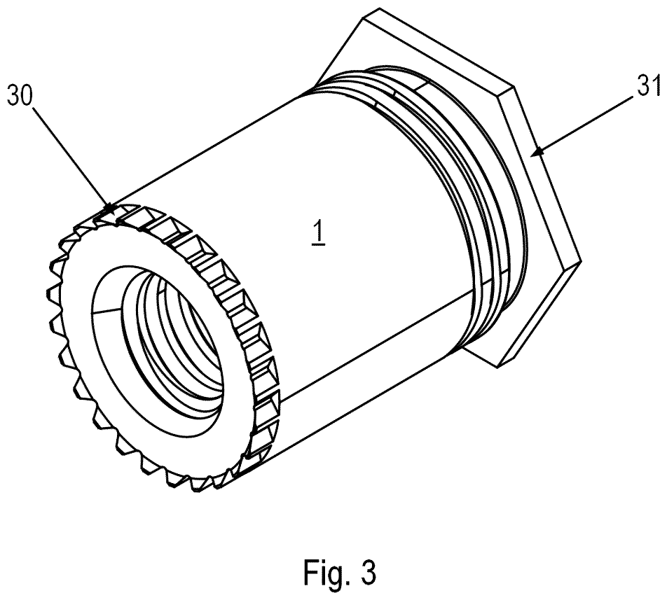

FIG. 4 illustrates the connection of the bushing 1 to a housing part 5 of the electrical device.

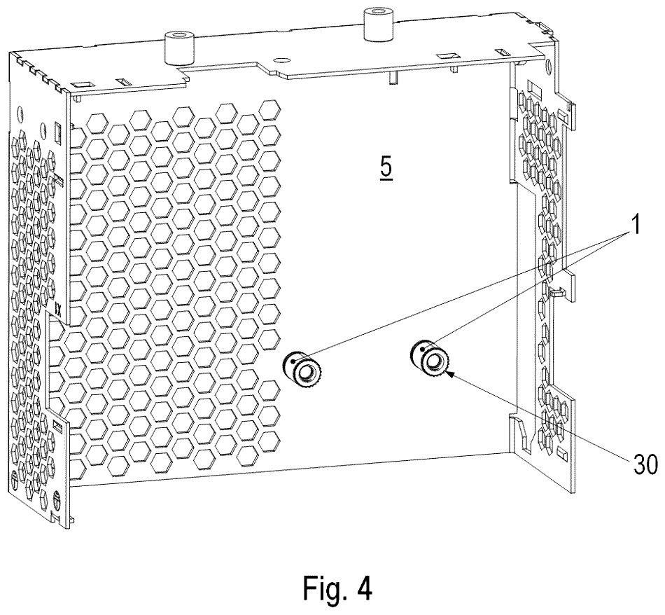

FIG. 5 is a perspective view of the signal electronics housing 50 of the electrical device.

FIG. 6 is a perspective view of a cover 60 of the electrical device.

FIG. 7 illustrates the cover 60 from a different viewing direction.

FIG. 8 is a perspective view of the electrical device without the signal electronics housing 50.

FIG. 9 is a perspective view of the electrical device.

FIG. 10 is a perspective view of the electrical device equipped with a fan.

FIG. 11 is a perspective view of the fan in a first viewing direction.

FIG. 12 is a perspective view of the electrical device.

FIG. 13 is a perspective view of the fan in a second viewing direction.

FIG. 14 is a perspective view of a line filter connectable or connected to the sheet-metal housing 80 of the electrical device, in which a protective cover 141 is provided to protect a ground connection provided by an angle bracket.

FIG. 15 is a perspective view of a holding part 143 for connecting the line filter to the sheet-metal housing 80.

FIG. 16 illustrates the electrical device with the line filter connected, in which the protective cover 141 is removed.

### DETAILED DESCRIPTION

As illustrated in the Figures, the electrical device has a printed circuit board 3, which is pressed towards a heat sink 2 by the screw head of a screw 4.

Thus, a heat-generating component, e.g., a power semiconductor component, equipped on the printed circuit board 3 is pressed against the heat sink 2, e.g., to improve the thermal coupling of the component to the heat sink 2.

The bushing 1 is, for example, arranged as a press-fit bushing.

The bushing 1 is plugged into a cut-out, e.g., an interruption, of a cooling fin 20 of the heat sink 2 and has an internal thread into which a threaded section of the screw 4 is screwed, and the bushing 1 is supported in the cooling fin 20 at a step of the cooling fin 20.

The bushing 1 has a polyhedral region 31, e.g., a hexagonal region, which projects from the cooling fin 20 and is pressed into a housing part 5 made of sheet-metal. Thus, the bushing 1 is embedded in the housing part 5 for conjoint rotation and connected for conjoint rotation with the housing part 5.

At the end region of the bushing 1 facing away from the polyhedral region 31, the bushing 1 has a toothing 30 with which the bushing 1 is plugged into the cooling fin 20 such that the toothing 30 is cut into the material of the cooling fin 20.

The heat sink 2 together with the cooling fin 20 is, for example, made of aluminum; the bushing 1 is, for example, made of steel.

The sheet-metal of the housing part 5 is, for example, made of sheet steel. For example, the housing part 5 is arranged as a punched and bent part.

The toothing 30 is arranged as an external toothing.

The housing part 5 is, for example, arranged on the side of the heat sink 2 facing away from the printed circuit board 3.

The housing part 5 is detachably connected to the heat sink.

A pressure plate 7 is arranged between the screw head and the printed circuit board 3 so that the force flow introduced by the screw 4 is spread out and thus the printed circuit board 3 is protected against excessive pressure. The pressure plate 7 is, for example, made of metal so that the housing part 5 is electrically connected to a conductive path of the printed circuit board 3 via the metal bushing 1 and the metal screw 4 as well as the metal pressure plate 7. In this manner, a ground connection and/or PE connection can be provided for the housing part 5.

The screw axis of the screw 4 is oriented perpendicular to the direction in which the cooling fin 20 extends.

For example, the component is a power module including multiple power semiconductors.

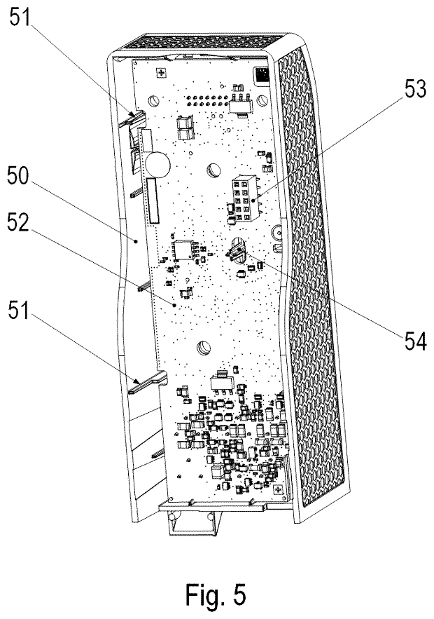

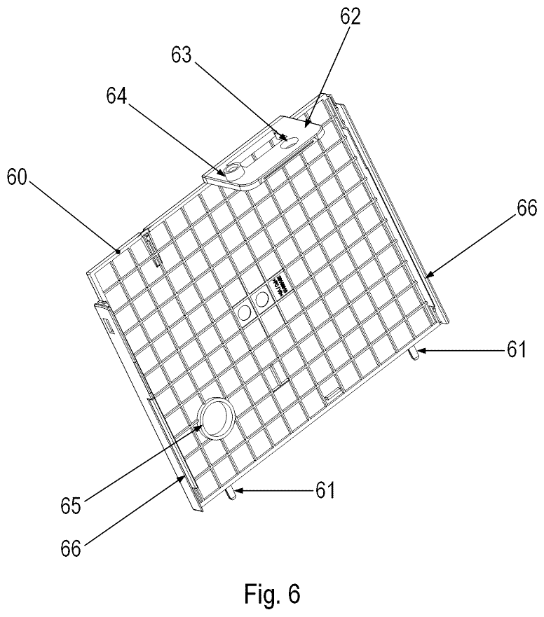

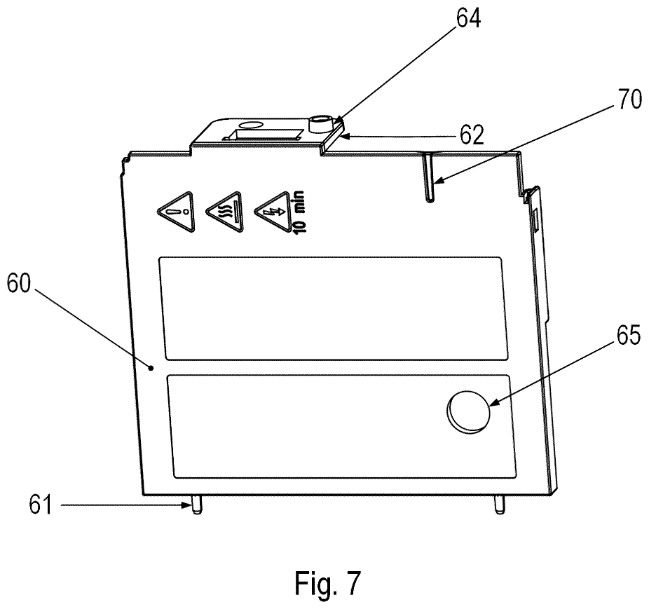

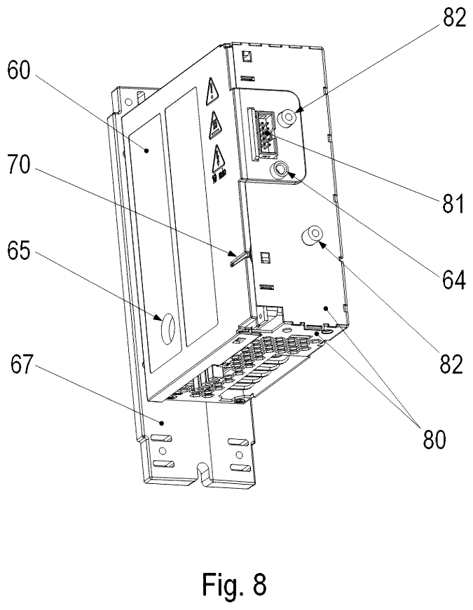

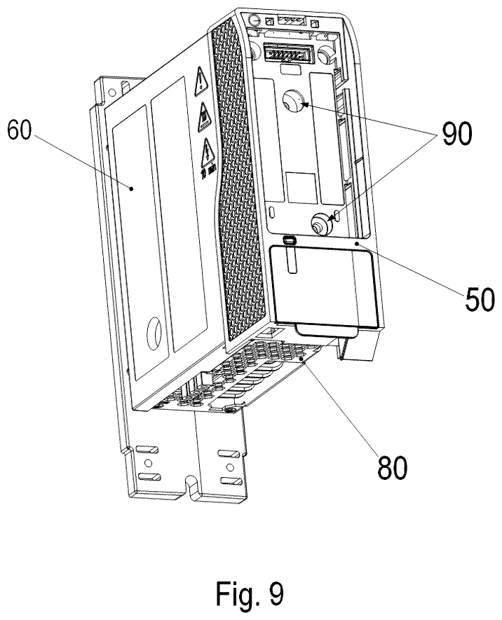

As illustrated in more detail in FIGS. 5 to 9, the electrical device, which is, for example, arranged as an inverter or converter, has a sheet-metal housing 80 which surrounds the power electronics of the electrical device to form a housing and is suitable for installation in a switch cabinet. On one side of the electrical device, the sheet-metal housing 80 is supplemented by a cover 60, e.g., a plastic cover, which is connected to the sheet-metal housing 80, and on a bottom side by a base plate 67.

Signal electronics, e.g., the signal electronics housing 50, is mounted on the power electronics, e.g., on the sheet-metal housing 80 together with the cover 60, and connected by screws.

The cover 60 is manufactured as an injection-molded plastic part and has projecting pins 61, which are plugged into recesses in the base plate 67. By a pivoting movement about the connecting line of the pins 61, sheet-metal edges of the sheet-metal housing 80 are pivoted into grooves 66 of the cover 60 during assembly of the electrical device.

Thus, at least one sheet-metal edge projects into one of the grooves 66 of the cover 60. Similarly, a further sheet-metal edge of the cover 60 projects into a further groove 66 of the cover 60. The cover 60 can thus be precisely aligned and centered in relation to the sheet-metal housing 80.

At its end region facing away from the pins 61, the cover 60 has a connecting lug 62, which is bent away from the rest of the cover 60 by a bending angle of 90°. This connecting lug 62 has a centering hole 63 passing through the connecting lug 62 and a projecting centering dome 64, which is hollow.

Thus, a first of the screws can be passed through the centering dome 64.

The cover 60 has a latching lug so that the cover 60 can be clip-connected to the sheet-metal housing 80.

The sheet-metal housing has at least two hollow centering domes 82, which are arranged as press-fit bushings or screw bushings and are connected to the sheet-metal housing 80 correspondingly.

One of the centering domes 82 projects through the centering hole 63 and thus supports the centering of the cover to the sheet-metal housing 80.

A second screw projects through the centering dome 82 projecting through the centering hole 63.

A mating plug connector part 81 projects through a further cut-out in the connecting lug 62.

The cover 60 has, on one of its sides, a guide groove 70, which guide groove 70 is oriented parallel to the plugging-on direction of the signal electronics.

When placing the signal electronics on the power electronics, the signal electronics housing 50 is guided such that tilting is prevented during placement.

For this purpose, the signal electronics housing 50 has at least one guide rib 51 on its inner side, which is received and guided in the guide groove 70, e.g., during placement of the signal electronics housing 50 on the sheet-metal housing 80.

A printed circuit board 52 equipped with signal electronics components is received in the signal electronics housing 50. In addition, the printed circuit board 52 is equipped with a plug connector part 53, which is brought into plug connection with the mating plug connector part 81 of the power electronics, which mating plug connector part 81 projects through the connecting lug 62.

Tilting is further prevented by the fact that a cross pin 54, which is formed on the signal electronics housing 50, projects into the centering dome 64.

Thus, the spatial alignment of the plug connector housing 50 relative to the power part of the electrical device is effected by the guide rib 51 or multiple such ribs, which project into corresponding guide grooves of the power part, together with the cross pin 54, which is plugged into the centering dome 64, and the plug connector part 53, which is or will be plug-connected to the mating plug connector part 81.

In addition, the centering domes 82 project into corresponding cavities of the signal electronics, so that, for example, coming from the outside, screws can be screwed through the signal electronics and through the cavities of the signal electronics and through the centering domes 82 into corresponding internal threads of the power electronics.

The cover 60 thus provides pre-centering during placement of the signal electronics and also is arranged as a housing for the power electronics. In addition, an RFID tag, which is arranged in the power electronics, can be read unhindered, as the cover 60 is made of plastic.

The cover 60 is readily labeled. In addition, warning notices can also be provided when shaping the cover 60, as well as type plate nests, i.e., recesses, that are suitable for attaching type plates.

The cover 60 is made of electrically insulating material.

The cover 60 also has a knockout region 60, so that after removing the knockout region 60 a screw of the power electronics can be actuated, e.g., rotated, by a tool, e.g., a screwdriver, and an electrical ground connection or electrical PE connection can be secured by the screw.

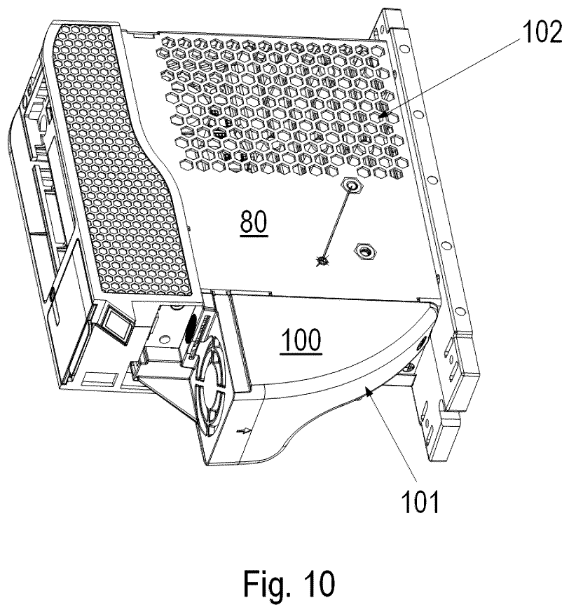

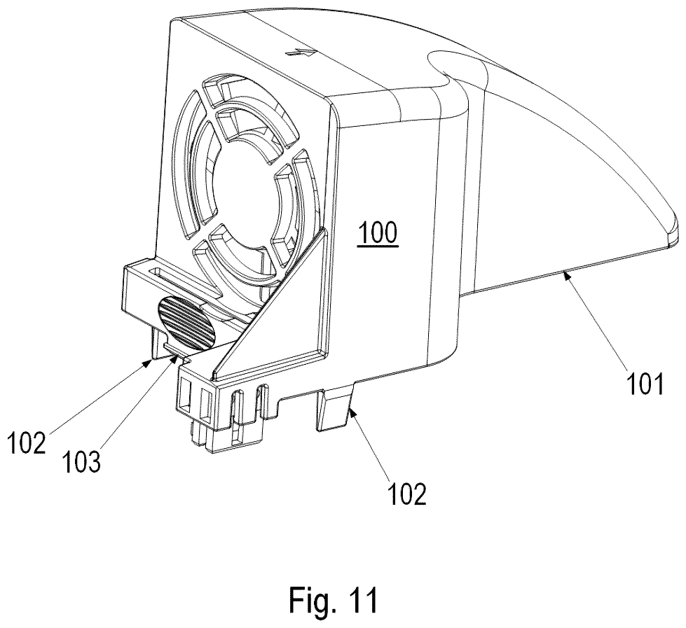

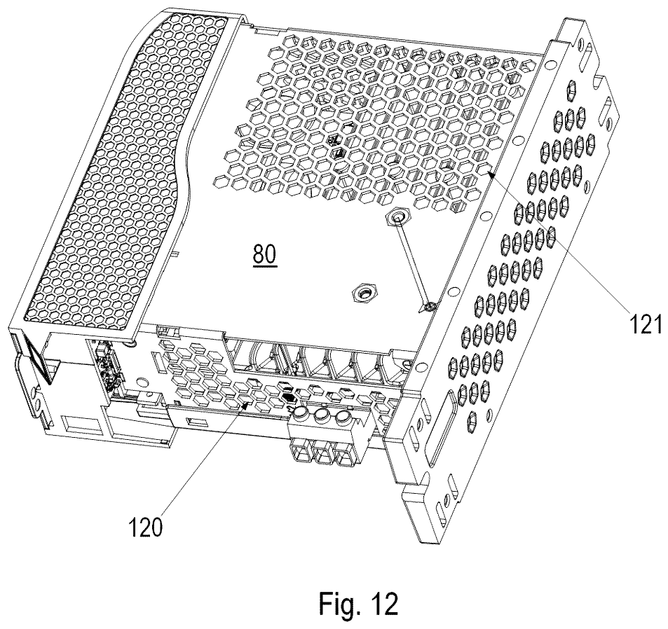

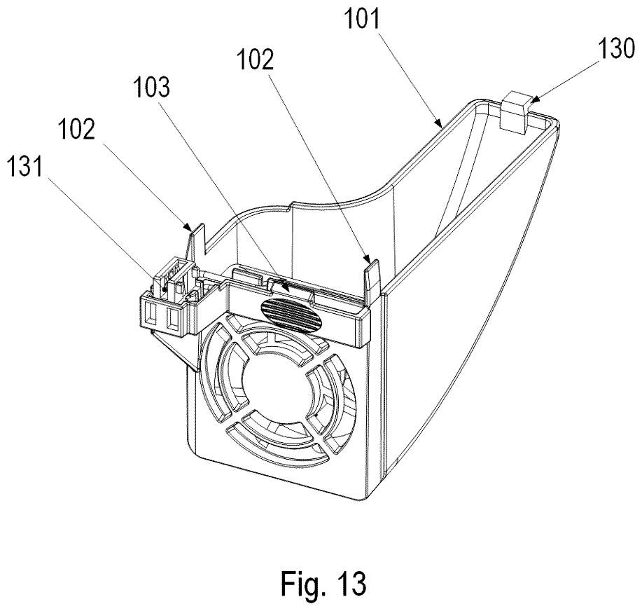

As illustrated in FIGS. 10 to 13, a fan can be fastened on the housing of the electrical device by first bringing the fan housing 100 into a pivot position, in which a pivot pin 130 of the fan housing 100 is set against an edge of the sheet-metal housing that is coaxially oriented with respect to the pivot axis, and then pivoting it about the pivot axis by a pivot angle, e. g., rotating it, whereby it is clip-connected to the sheet-metal housing 10.

The fan has a fan housing 100, which has a receiving region for an electric motor that drives a fan wheel, and a narrowed region in which the air flow conveyed by the fan wheel is narrowed and thus has a higher speed. In addition, the narrowed region 101 is curved such that the air flow conveyed by the fan wheel is deflected by 90° and directed into the interior of the electrical device through front grille openings 120, which, for example, are thus facing the fan.

The air flow flowing through the electrical device additionally draws in an additional air flow through grille openings 121 arranged on the side of the electrical device, which air flow thus increases the volume flow and also cools the heat loss sources of the electrical device arranged on the side and also the sheet-metal housing 80.

Further grille openings are arranged on the side of the electrical device opposite the fan, through which further grille openings the entire air flow exits.

In this manner, the air flow coming from the fan and entering the electrical device at a high flow rate ensures efficient cooling of the electrical device.

When the fan housing 100 is clip-connected to the sheet-metal housing 80, the fan housing 100 is clip-connected by the latching lug 103 formed on the fan housing 100, while two pivot pins 130 formed on the fan housing 100 and spaced apart from one another project into recesses in the sheet-metal housing 80 and guide the fan housing 100, e.g., in this final phase of the pivoting movement.

The fan also has a plug connector part 131 which comes into plug-in contact with a mating plug connector part fastened to the sheet-metal housing 80 when the described pivoting movement is carried out. The fan can thus be supplied electrically.

As the distance to the fan wheel increases, the flow cross-section in the narrowed region decreases monotonically, in which initially a width of the interior region of the fan made available to the air flow by the fan hood becomes monotonically smaller and then a height of the interior region of the fan made available to the air flow by the fan hood becomes increasingly smaller. For example, the width is measured in a direction parallel to the nearest surface of the sheet-metal housing and the height is measured in a direction parallel to the normal direction of the nearest, e.g., flat, surface.

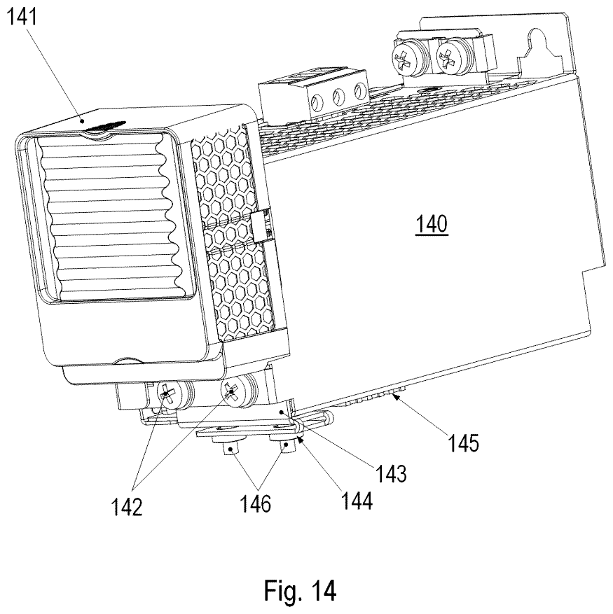

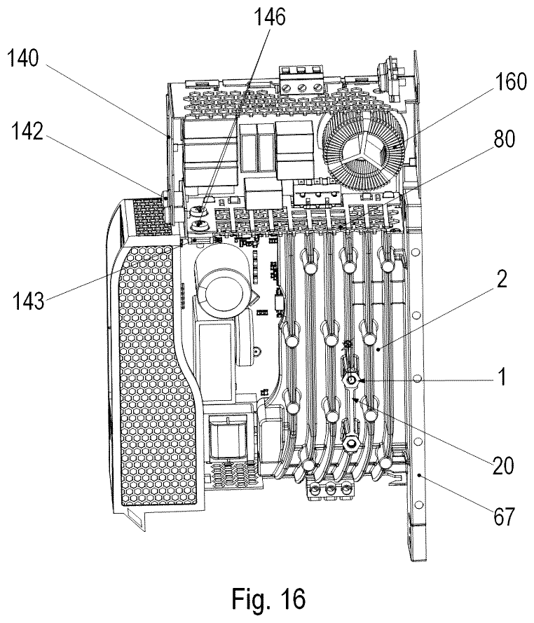

As illustrated in FIGS. 14 to 16, the line filter has a housing 140 whose heat loss is dissipated by the air flow exiting the sheet-metal housing, in that the air flow exiting the sheet-metal housing 80 enters the interior region of the line filter enclosed by the housing 140, flows through the interior region and exits on the other side of the housing 140, i.e., on the side of the line filter facing away from the sheet-metal housing 80.

The line filter is fastened to the sheet-metal housing 80.

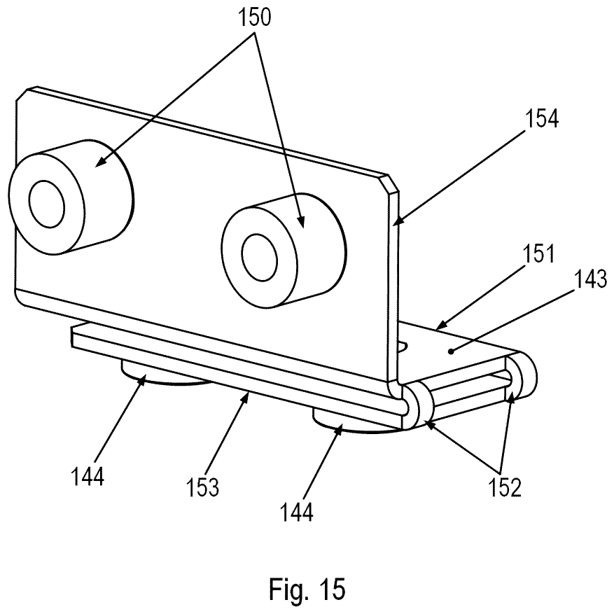

For this purpose, an angle bracket 143 made of sheet metal as a punched and bent part is used, which is illustrated in more detail in FIG. 15.

The angle bracket 143 has a first limb region 151, which is connected to a second limb region 153 via a yoke region 152.

The first limb region 151 is, for example, arranged parallel to the second limb region 153.

For example, the first limb region 151, the yoke region 152 and the second limb region 153 have a U-shape.

The first limb region 151, the yoke region 152 and the second limb region 153 are formed in one piece, e.g., in one part, together with a lug region 154.

Press-in nuts 150 are arranged in the lug region 154 and connected, e.g., in a force-locking and/or material-bonding manner.

Further press-in nuts 144 are arranged in the second limb region 153 and are connected, e.g., in a force-locking and/or material-bonding manner.

The lug region 154 adjoins the first limb region 151 and is bent at a right angle at the first limb region 151. Thus, the lug region 154 is oriented at a right angle to the first limb region 151 and also to the second limb region 153.

For example, the first limb region 151, the second limb region 153 and also the lug region 154 are flat.

A respective screw 146 projects through the first limb region 151, the second limb region 153 and the sheet-metal housing 80, and the sheet-metal housing 80 projects between the first limb region 151 and the second limb region 153. During assembly, the angle bracket 143 with the opening of the U is thus plugged onto a sheet-metal section of the sheet-metal housing 80 and connected to the sheet-metal section by the screws 146 by screwing the screws 146 into the press-in nuts 144. Thus, the U-shaped region of the angle bracket 143 clamps onto the sheet-metal section. As a result, the lug section 154 projects, for example, perpendicularly, and provides a fastening option for the line filter.

For example, the respective screw head of the respective screw 146 rests directly against the first limb region 151 and thus presses the first limb region 151 against the sheet-metal section, which, in turn, is pressed against the second limb region 153.

To fasten the line filter, the housing 140 of the line filter is placed against the sheet-metal housing 80, and screws 142, which project through the housing 140 of the line filter, are screwed into the press-in nuts 150 arranged in the lug region 154. Thus, the respective screw head of the screws 142 presses the housing 140 against the press-in nuts 150.

In this manner, the line filter is connected to the sheet-metal housing, and this connection can be used as an electrical ground connection or PE connection, because both two screws 146 are used for fastening to the sheet-metal housing and two screws 142 are used for fastening to the housing 140 of the line filter. Because if a particular screw fails, the safety of the PE connection or ground connection is still guaranteed. It is thus important that at least two press-in nuts 144 are provided at the second limb region 153 and two press-in nuts 150 are provided at the lug region 154.

The protective cover 141 made of plastic is arranged on the housing 140 in a displaceable manner, so that in a first displacement position the angle bracket 143 is accessible from the surroundings of the electrical device. The screws 142 can thus be actuated. In a second displacement position, the angle bracket 143 is protected by the protective cover 141 and is thus not accessible from the surroundings.

For example, the yoke region 152 is formed from two spaced-apart partial regions, and these, however, as described above, together with the limb regions (153, 151) and the lug region 154 form the angle bracket 143, which is formed in one piece, e.g., in one part.

When attaching the line filter to the sheet-metal housing, a plug connector is activated at the same time. The line filter contains a choke 160 via which the mains current supplying the power electronics is routed. In this manner, interference voltage signals generated by the power electronics are kept away from the electrical supply network.

### LIST OF REFERENCE NUMERALS

1 Bushing, e. g., press-fit bushing
2 Heat sink
3 Printed circuit board
4 Screw
5 Housing part
6 Heat-generating component
7 Pressure plate
20 Cooling fin
30 Toothing
31 Polyhedral region, e.g., hexagonal region
50 Signal electronics housing
51 Guide rib
52 Printed circuit board with signal electronics components
53 Plug connector part
54 Cross pin
60 Cover, e.g., plastic cover
61 Pin
62 Connecting lug
63 Centering hole
64 Centering dome
65 Knockout region
66 Groove
67 Base plate
70 Guide groove
80 Sheet-metal housing for power electronics
81 Mating plug connector part
82 Centering dome
90 Cut-out, passing through the signal electronics housing 50
100 Fan housing
101 Narrowed region of the fan housing 100
102 Guide pin
103 Latching lug
120 Front grille openings
121 Side grille openings
130 Pivot pin
131 Plug connector part
140 Housing
141 Protective cover
142 Second screw
143 Angle bracket
144 Press-in nut
145 Plug connector part
146 First screw
150 Press-in nut
151 First limb region
152 Yoke region
153 Second limb region
154 Lug region
160 Choke

1-15. (canceled)

16. An electrical device, comprising:
power electronics including a sheet-metal housing;
a line filter including a housing;
an angle bracket configured to provide an electrical PE connection and/or ground connection between the sheet-metal housing and the housing;
wherein the angle bracket includes a first limb region, a second limb region, a yoke region connected to the first limb region and the second limb region, and a lug region;
wherein at least two first press-in nuts are arranged in the second limb region and at least two second press-in nuts are arranged in the lug region;
wherein the angle bracket is arranged on a sheet-metal region of the sheet-metal housing, the sheet-metal region being arranged between the first limb region and the second limb region and contacts the first limb region and the second limb region;
wherein first screws are screwed into the first press-in nuts and project through the first limb region, the sheet-metal region, and the second limb region, clamping the sheet-metal region between the first limb region and the second limb region;
wherein second screws are screwed into the second press-in nuts and project through the housing.

17. The electrical device according to claim 16, wherein the first limb region is spaced apart from the second limb region, the yoke region, the first limb region, and the second limb region form a U-shaped region of the angle bracket, the lug region is adjacent to the first limb region, a screw head of the first screw presses the first limb region onto the sheet-metal region and presses the sheet-metal region onto the second limb region, and a screw head of the second screw presses the housing onto the lug region.

18. The electrical device according to claim 16, wherein the angle bracket is arranged as a punched and bent sheet metal component.

19. The electrical device according to claim 16, wherein a protective cover is arranged on the housing in a displaceable manner, in a first displacement position of the protective cover, the angle bracket being accessible from surroundings of the electrical device, and, in a second displacement position the protective cover surrounds the angle bracket in a housing-forming manner and the angle bracket is inaccessible from the surroundings.

20. The electrical device according to claim 16, wherein a plug connector part is arranged on the line filter and is plug-connected to a corresponding mating plug connector part of the power electronics.

21. The electrical device according to claim 16, wherein the lug region on the first limb region is bent at a right angle.

22. The electrical device according to claim 16, wherein the line filter includes a choke configured to conduct current that supplies the power electronics.

23. The electrical device according to claim 16, wherein air flow exiting the sheet-metal housing flows through the housing of the line filter.

24. The electrical device according to claim 16, further comprising a fan including a fan housing clip-connected to the sheet-metal housing and including a pivot pin is set against a pivot axis oriented coaxially to an edge of the sheet-metal housing configured to pivot the fan relative to the sheet-metal housing.

25. The electrical device according to claim 24, wherein the pivot pin is set against a pivot axis oriented coaxially to an edge of the sheet-metal housing configured to rotate the fan relative to the sheet-metal housing, and the clip connection blocks pivoting of the fan, and release of the clop connection permits pivoting of the fan.

26. The electrical device according to claim 24, wherein the fan housing includes a latching lug clipped into a recess or cut-out in the sheet-metal housing, the fan housing includes guide pins configured to guide the fan housing at least when releasing or closing the clip connection, the fan housing, including the pivot pin, the guide pin, and/or the latching lug is made of injection-molded plastic, and/or the fan housing includes a receiving region for a fan wheel driven by an electric motor and a narrowed region configured to narrow an air flow conveyed by the fan wheel as the air flow flows through the narrowed region and to increasing an average flow velocity of the air flow.

27. The electrical device according to claim 26, wherein the narrowed section is rounded and is configured to deflect the air flow flowing through the narrowed section by 90° from the fan in a direction perpendicular to a rotational axis of the fan wheel and to flow through front grille openings of the sheet-metal housing into an interior of the electrical appliance and/or into an interior region enclosed by the sheet-metal housing.

28. The electrical device according to claim 27, wherein the sheet-metal housing includes further grille openings arranged on a side of the electrical device and adapted to draw in an additional air flow by the air flow flowing through the electrical device

29. The electrical device according to claim 28, wherein the additional air flow increases a volume flow and cools laterally arranged heat loss sources of the electrical device and the sheet-metal housing, third grille openings being arranged on a side of the electrical device opposite the fan and being arranged as an exit for an entire air flow exits.

30. The electrical device according to claim 26, wherein the narrowed region has a flow cross-section that decreases monotonically with increasing distance from the fan wheel.

31. The electrical device according to claim 30, wherein initially a width of an interior region of the fan becomes monotonically smaller and then a height of the interior region of the fan becomes increasingly smaller.

32. The electrical device according to claim 16, further comprising signal electronics, the sheet-metal housing including a cover configured to form a housing, the signal electronics including a signal electronics housing arranged on the power electronics, the cover including a connecting tab, through which a mating plug connector part of the power electronics projects, a plug connector part of the signal electronics being connected to the mating plug connector part, the covering including a guide groove, an inner side of the signal electronics housing including a guide rib that projects into and/or is guided by the guide groove, at least one first centering dome being is arranged on the sheet-metal housing and projecting towards the signal electronics housing, a screw projecting through a centering dome and through the signal electronics housing and being screwed into a threaded bore of the power electronics, a plastic hollow centering dome being arranged on a connecting lug and projects toward the signal electronics housing, the signal electronics housing including a pin that projects into the hollow centering dome

33. The electrical device according to claim 32, wherein the pin is configured to center the signal electronics housing relative to the sheet-metal housing.

34. The electrical device according to claim 16, wherein the connecting lug is arranged at an angle, the cover is arranged as an injection-molded plastic part, pins arranged on and projecting from the cover extending into recesses and/or cut-outs in a base plate of the electrical device, the sheet-metal housing is connected to the base plate, and/or a sheet-metal edge of the sheet-metal housing projects into a groove of the cover.

35. The electrical device according to claim 34, wherein the sheet-metal edge is configured to pivot into the groove by a pivoting movement about a connecting line of the pins.

36. The electrical device according to claim 16, wherein the cover has a knockout region, through which a screw becomes accessible after knocking out the knockout region, the screw securing an electrical ground connection and/or a PE connection.

37. The electrical device according to claim 16, further comprising a printed circuit board including a heat-generating component, a heat sink including at least one cooling fin, and a housing part of the sheet-metal, a bushing being arranged in a cut-out in the cooling fin, a screw being screwed into an internal thread of the bushing, a screw head of the screw presses the printed circuit board, together with the component, toward the heat sink, the bushing including a polyhedral region pressed into the housing part.

38. The electrical device according to claim 37, wherein the bushing includes a toothing which is cut into the material of the cooling fin, the toothing is arranged an external toothing, the screw projects through the heat sink and/or through the cooling fin, the housing part is arranged on a side of the heat sink facing away from the printed circuit board, the printed circuit board is arranged on a side of the heat sink facing away from the housing part, the housing part is arranged as a punched and bent part from a sheet metal, the polyhedral region is arranged flush with the housing part on at least one side of the housing part and/or on a side of the housing part facing away from the heat sink, the polyhedral region projects radially from the bushing, the polyhedral region is spaced from the toothing, the recess is arranged as an interruption in the cooling fin, the bushing is made of steel, the heat sink is made of aluminum, and/or the cooling fin has a thickening interrupted by the recess.

39. The electrical device according to claim 38, wherein a further bushing is arranged in a further recess of a further cooling fin of the heat sink, a further screw is screwed into an internal thread of the further bushing and includes a screw head that presses the printed circuit board, together with a further component, toward the heat sink, the further bushing includes a further polyhedral region pressed into the housing part, the further bushing includes a further toothing that cuts into a material of the further cooling fin, the further toothing is arranged as an external toothing, and the further screw projects through the heat sink and/or through the further cooling fin.
